(19) United States
(12) Patent Application Publication
(10) Pub. No.: US 2002/0003693 A1
(43) Pub. Date: Jan. 10, 2002

(54) Heat sink

(76) Inventor: Osamu Namatame, Hitachioota (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/875,982

(22) Filed: Jun. 8, 2001

(30) Foreign Application Priority Data
Jun. 9, 2000 (JP) 2000-179362

(51) Int. Cl. H05K 7/20; H01L 23/26; F28F 7/00

(52) U.S. Cl. 361/704; 165/185; 165/80.3; 174/16.3

(57) ABSTRACT

A heat sink comprises a heat radiating plate having a plurality of radiating through holes and a plurality of radiating fins formed on the plate, and the radiating fins are extended from the surface of the heat radiating plate.

### BACKGROUND OF THE INVENTION

The present invention relates to a heat sink for radiating the heat from devices, such as electronic parts and elements.

Semiconductor devices used in domestic electric products, automobiles and computers hate heat and it is strongly required to prevent their inner temperature from exceeding an allowable maximum temperature.

Power transistors and semiconductor rectifiers consume a great deal of power and it is impossible to discharge generated heat by way of their cases of the semiconductor elements and leads and therefore, the devices are destroyed by increasing of the inner temperature. To avoid the thermal destruction, a heat sink with large radiation area is attached to the cases of the semiconductors. The effect of the heat radiation is getting bigger in proportion to the increase of the radiating area and the thickness of the heat sink. As a result, the devices is able to control higher power.

In the ordinary devices, it is well-known to prepare a circular hole or long hole for radiation to the radiating palate, or to attach radiating fins to the surface of the radiating plate.

### SUMMARY OF THE INVENTION

An object of the present invention is to provide a heat sink with high radiation effect and capable of decreasing the inner temperature of the devices.

One feature of the present invention is to provide a heat sink comprising a heat radiating plate having a plurality of radiating through holes and a plurality of radiating fins formed on the heat radiating plate, and the radiating fins being extended from the surface of the heat radiating plate.

### BRIEF DESCRIPTION OF THE DRAWINGS

FIG. 1 is a diagrammatical view showing an experimental facility for confirming the radiation effect of the heat sink according to the present invention;

FIG. 2 is a model view showing a heat sink according to an embodiment of the present invention;

FIG. 3 is a view showing measuring result of the heat sink according to the present invention;

FIG. 4 is a view showing a temperature measuring result of the heat sink of the comparison example;

FIG. 5 is a view showing temperature measuring result of a heat sink according to the second embodiment of the present invention; and

FIG. 6 is a view showing measuring result of the sink according to third embodiment of the present invention.

FIG. 7 is a plane view showing a heat sink according to fourth embodiment of the present invention.

FIG. 8 is a sectional partial view along the line IIX-IIX in FIG. 7.

### DETAILED EXPALANATION OF THE PREFERRED EMBODIMENTS

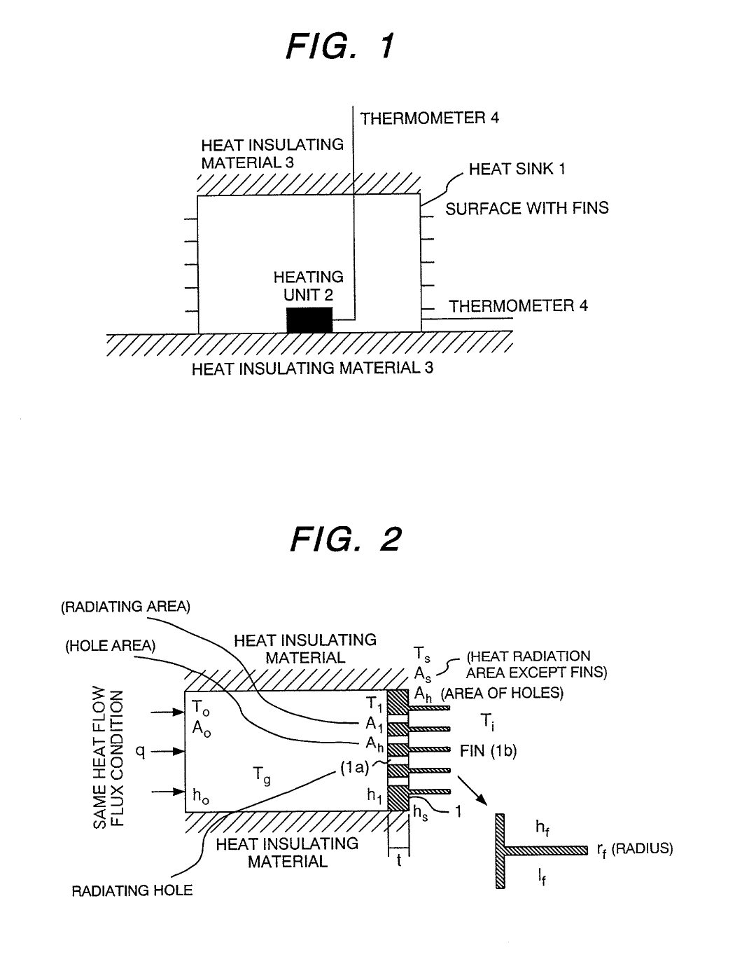

FIG. 1 is a diagramatical view showing an experimental facility for confirming the heat radiation effect of the heat sink according to the present invention.

The confirmation on radiation effect by heat sink is carried out by the following steps:

(1) As shown in FIG. 1, an iron cover 1 with fins (heat sink), a heating unit 2 (heater) a heat insulating material 3 a thermometers 4 (thermocouple) are prepared.

(2) The heating unit 2 is covered with the cover 1 and the room temperature is maintained at a predetermined value.

(3) When the measured temperature become stable, the temperature is measured at the steady-state.

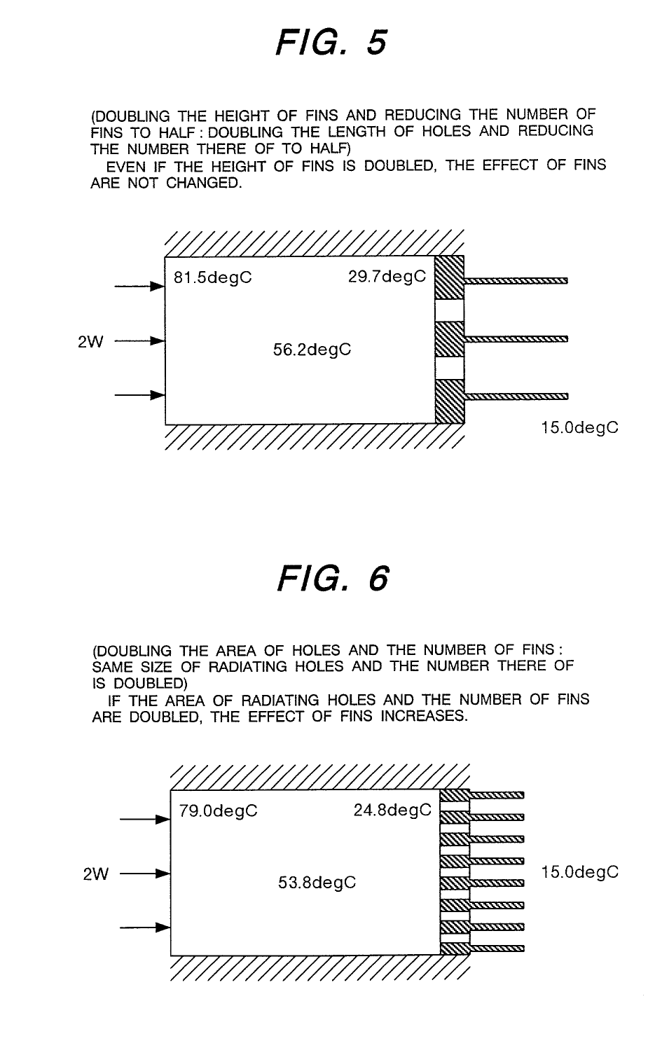

Above temperature measurement steps are repeated on every cover 1 as shown in FIGS. 2 to 6. If the temperature of the heating unit 2 becomes law, it shows that radiation characteristic of the cover 1 is well.

FIG. 2 is a model view of a heat sink showing an embodiment of the present invention.

The surface of a heat radiation plate 1 has a plurality of radiating holes 1a and fins 1b as shown in FIG. 2.

(1) In FIG. 2, the meaning of the reference signs areas follows:

A:area

C:specific heat

Gr:Grashof number

h:heat conductivity

l:length, n:number of fins

Pr:Prandtl number

q:heat flux

r:radius

t:thickness of wall

T:temperature

Ub:non-dimension number

v:exchange flow speed of radiating hole

Ö:efficency of fin

ó:density

sufix 0,1,s,f:position

sufix g:air of vessel

sufix h:heat radiating hole

(2-1) Heat balance formulas of FIG. 2 are expressed as follows:

q₀=h₀A₀(T₀−T_{g})

q₁=h₁A₁(T_{g}−T₁)

qₛ=(KₛA₁/t)(T_{g}−Tₛ)1

qₕ=VₕAₕó^{g}C_{g}(T_{g}−Tᵢ)

q_{f}=hₛAₛ(Tₛ−Tᵢ)+Önh_{f}A_{f}(Tₛ−Tᵢ)

q₀=q₁+qₕ=qₛ+qₕ=q_{f}+qₕ

(2-2) heat transfer coefficient is expressed by the following formula:

(2-3) brief formula to heat transfer of natural convection of laminar flow(10⁴<GrPr<10⁹) at atmospheric pressure are expressed as follows:

(2-4) vertical plane palate

h₀=1.42{(T₀−T_{g})/l_{s}}^{¼}

h₁=1.42{(T_{g}−T₁)/l_{s}}^{¼}

hₛ=1.42{(Tₛ−Tᵢ)/l_{s}}^{¼}

(2-5) horizontal column

h_{f}=1.32{(Tₛ−Tᵢ)/(2r_{f})}^{¼}

(2-6) efficiency of the fin

Ö=tanh Uₚ/U_{b}

U_{b}=2^{½}l_{f}{h_{f}/Kₛr_{f})}^{½}

(2-7) setting of parameters

q=2W, Tᵢ=15degC, K=204W/mK(at20degC), C_{g}=1000J/KgK(at 300K)

ó_{g}=1.18 kg/m³ (at 300K)

l₀=l₁=lₛ=0.1 m,

A₀=0.014 m²,r_{f}=0.001 m,l_{f}=0.005 m,t=0.001 m,n=160

vₕ=0.002 m/s

Aₕ=(0.01×0.003×80)/(0.14×0.1)×A₀=0.171A₀=0.0024 m²

A₁=Aₛ=A₀−Aₕ=0.0116 m²

A_{f}=πr_{f}²+2πrl_{f}=3.46×10⁻⁵m²

(2-8) basic calculation

(calculation of heat transfer coefficient)

Assuming (Tₛ−Tᵢ)=14degC, hₛ=1.42{(Tₛ−T₁)/l₁)}^{¼}=4.88W/m²K hₛ=1.32{(Tₛ−T₁)/2r_{f})}^{¼}=12.1W/m²K.

Assuming (T_{g}−T₁)=27degC, h₁=1.42{(T_{g}−T₁)/lₛ}^{¼}=5.76W/m²K.

Assuming (T₀−T_{g})=25degC, h₀=1.42{(T₀−T_{g})/lₛ}^{¼}=5.65W/m²K.

(2-9) calculation of efficiency of the fins

U_{b}=2^{½}l_{f}{h_{f}/Kₛr_{f})}^{½}=0.0545

ö=tanh Uₚ/U_{b}=0.999

(2-10) Calculation of Heat flux and temperature

q₁=hₛAₛ(Tₛ−T₁)+Onh_{f}Aₜ(Tₛ−T₁=a(Tₛ−T₁)

qₕ=(VₕAₕóC_{g}(T_{g}−T₁)=b(T_{g}−T₁)

qₛ=KₛA₁/t)(T₁−Tₛ)=c(T₁−Tₛ)

q₁=h₁A₁/t)(T_{g}−T₁)=d(T_{g}−T₁)

q₀=h₀A₀/t)(T₀−T_{g})=e(T₀−T_{g})

a=0.124,b=0.00566,c=2370,d=0.0668,e=0.0791

From qₛ=q₁, (a+c)Tₛ−cT₁=T₁

From q₁=q_{f}, aTₛ−dT_{g}+dT₁=aT₁

(ac+ad+cd)T₁−d(a+c)T_{g}=acT₁- - - (1)

From q₀=q₁+qₕ, (b+d)T_{g}−öT₁=q₀+bT₁- - - (2)

By inserting values into formulas (1) and (2),

452.2T₁−158.3T_{g}=4408

0.07246T_{g}−0.0668T₁=2.085

T₁29.27degC

T_{g}=55.76degC

Tₛ={c/(a/(a+c)}T₁+{a/(a+c)}T₁=29.27degC

T₀=2/e+T_{g}=81.04degC

FIG. 3 shows the above result.

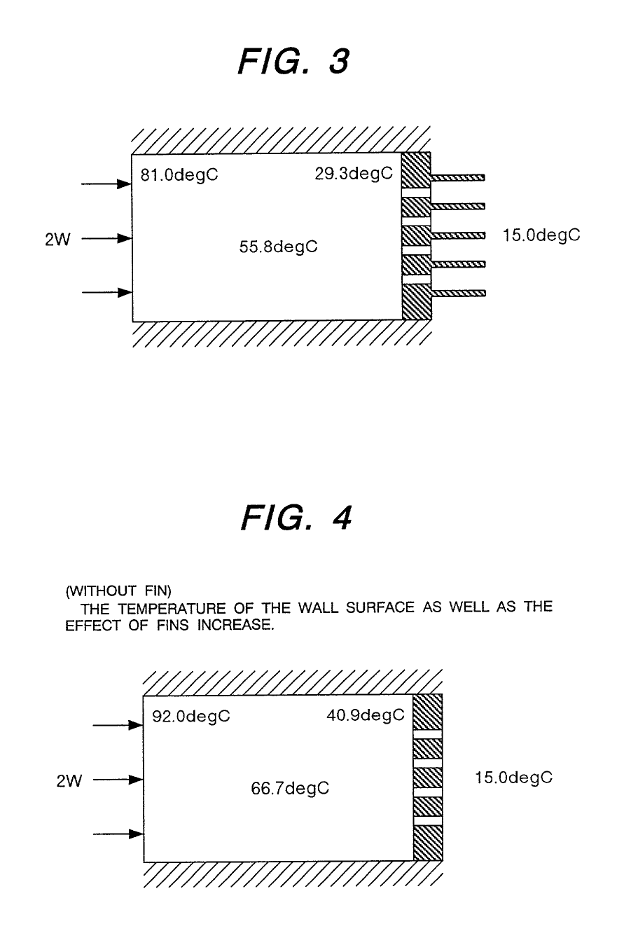

(3-1) heat balance of the heat sink without fins of FIG. 4 is expressed as follows)

qₜ=hₛAₛ(Tₛ−T₁)+Önh_{f}Aₜ(Tₛ−T₁)

(3-2) calculation of heat transfer

(Tₛ−T)=26degC

hₛ=1.42{(Tₛ−T₁)/lₛ)}^{¼}=5.70W/m²K

(T_{g}−T₁)=26degC

h₁=1.42 {(T_{g}−T₁)/ Iₛ}^{¼}=5.70W/m²K

(T₀−T_{g})=25degC

h₀=1.42{(T₀−T_{g})/lₛ}^{¼}=5.65W/m²K

(3-3) calculation of heat flux and temperature

q_{f}=hₛAₛ(Tₛ−T₁)=a(Tₛ−T₁)

a=0.0.0661,b=0.00566,c=2370,d=0.0661,e=0.0791

By inserting values into the formulas (1) and (2),

313.3T₁−156.7T_{g}=2350

0.07176T_{g}−0.0661T₁=2.085

T₁=40.86degC

T_{g}=66.69degC

Tₛ={c/(a+c)}T₁+{a/(a+c)}T₁=40.86degC

T₀=2/e+T_{g}=91.97degC

FIG. 4 shows the above result.

In case of the heat sink without fins, the temperature of the wall increases and it shows a great deal of effect of the fins.

(4) Doubling height of fins, reducing the number of fins to half: doubling length of radiating hole and reducing the number of fins

(4-1) Setting of parameters

l_{f}=0.01m, n=80, A_{f}=πr_{f}²+2πr_{f}l_{f}=6.60×10⁻⁵m²

(4-2) calculation of heat transfer)

Assuming (Tₛ−T₁)=14degC,

hₛ=1.42{(Tₛ−T₁)/lₛ}^{¼}=4.88W/m²K

h_{f}=1.32{(Tₛ−T₁)/2rₜ)}^{¼}=12.1W/m²K

Assuming (T_{g-T}₁)=27degC,

h₁=1.42{(T_{g}−T₁)/lₛ}^{¼}=5.76W/m²K

Assuming (T₀−T_{g})=25degC,

h₀=1.42{(T₀−T_{g})/lₛ}^{¼}=5.65W/m²K

(4-3) calculation of the effect of fins

U_{b}=2^{½} l_{f}{h_{f}/Kₛr_{f})}^{½}=0.109

Ö=tanh Uₚ/U_{b}=0.996

(4-4) calculation of heat flux and temperature

a=0.120, b=0.00566, c=2370, d=0.0668, e=0.0791

By inserting values,

442.7T₁−178.2T_{g}=4266

0.07246T_{g}−0.0668T_{g}=2.085

T₁=29.73degC

T_{g}=56.21degC

Tₛ={c/(a+c)}T₁+{a/(a+c)}T₁=29.73degC

T₀=2/e+T_{g}=81.47degC

Fi.5 shows the above result. Even if the height of fins become twice, the radiation effect is almost not changed.

(5) Doubling the radiating hole area and the number of fins: same size of radiating hole and twice number of fin

(5-1) setting of parameter

n=320

Aₕ=(0.01×0.003×160)/(0.14×0.1)×A₀=0.17180A₀=0.0048m

A₁=Aₛ=A₀−Aₕ=0.0092m²

(5-2) calculation of heat transfer

Assuming (Tₛ−T₁)=9degC,

hₛ=1.42{(Tₛ−T₁)/lₛ}^{¼}=4.37W/m²K

h_{f}=1.32{(Tₛ−T₁)/2r_{f})}^{¼}=10.8W/m²K

Assuming (T_{g}−T₁)=27degC,

h₁=1.42{(T_{g}−T₁)/lₛ}^{¼}=5.86W/m²K

Assuming (T₀−T_{g})=25degC,

h₀=1.42{(T₀−T_{g})/lₛ}^{¼}=5.65W/m²K

(5-3) efficiency of fins

U_{b}=2^{½ l}_{f} {h_{f}/Kₛr_{f})}^{½}=0.0514

Ö=tanh U_{b}/U_{b}=0.999

(5-4) calculation of heat flux and temperature

a=0.160, b=0.0113, c=1880, d=0.0539, e=0.0791

By inserting formulas (1) and (2),

402.1T₁−101.3T_{g}=4512

0.0652T_{g}−0.0539T₁=2.170

T₁=24.76degC

T_{g}=53.76degC

Tₛ={c/(a+c)}T₁+{a/(a+c)}T₁=24.76degC

T₀=2/e+T_{g}=79.04degC

FIG. 6 show the above result.

When doubling the area of the heating through hole and the number of radiating fins, the radiating effect is a little improved as shown in FIG. 6.

According to the embodiment of the invention, the radiation effect of the present invention is improved and it is possible to reduce the inner temperature in comparison with traditional heat sink

The above explanation shows that iron is used as the cover 1 with fins. However, the radiation effect is improved in comparison with the traditional heat sink when using aluminum and copper, and the inner temperature of the element may be reduced.

The shape of the heat sink 1 may be box type and the radiating element is inserted into the box shown in FIG. 1 or to attach radiating element to the surface of the radiating surface as shown in FIGS. 2 to 3 and 5 to 6. It is selectable to attach the element in according to the environment of use.

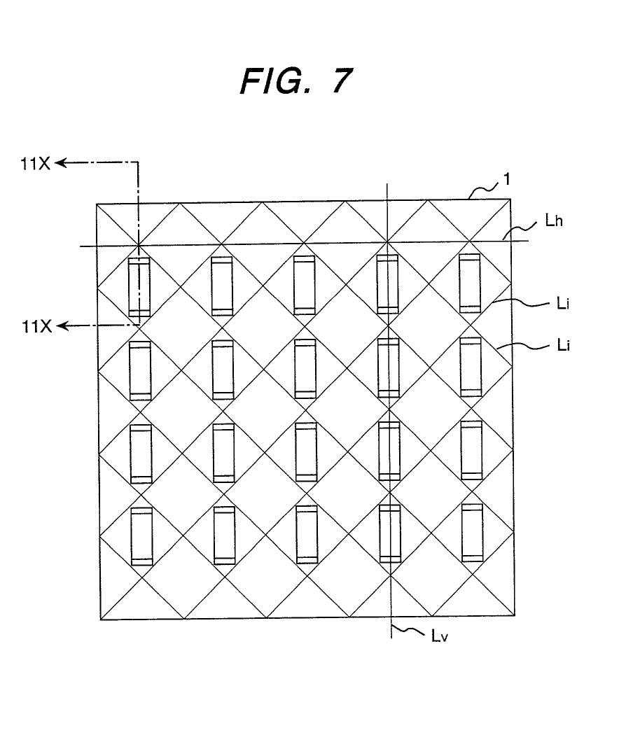

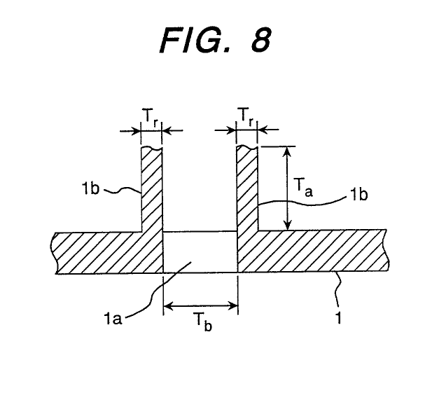

In manufacturing the heat sink according to the present invention, surface of the heat radiating plate 1 is cut and a plurality of claws are raised up as shown in FIGS. 7 and 8. The raised-up claws are used as radiating fins 1b and through holes 1a made by cutting radiating plate and raising up claws are used as heat radiating through hole 1a.

The radiating through holes 1a may be shape of rectangular and the radiating fins 1b are positioned in opposition to each other at each side of the radiating through holes 1a as shown in FIG. 8, the sum 2Ta of heights of the fins 1b positioned both sides of the radiating through holes 1a is larger than the distance Tb between the both radiating fins 1b. The thickness Tr of the radiating fins 1b is thinner than that of the radiating plate 1 as shown in Fig.8.

The heat radiating fins 1b are arranged along horizontal lines Lh, vertical lines Lv and inclined lines Li inclined at a predetermined degree, for example, 45 degree to the horizontal and vertical lines so as to allow cooling air to flow along the aligned radiating fins as shown in FIG. 7.

According to the above manufacturing process , both the radiating fins and through holes are formed simultaneously only by cutting and raising up the claws on the radiating plate. Therefore, it is possible to shorten manufacturing process in comparison with the ordinary process wherein the radiating fins are attached by welding or other way to the surface of heat radiating plate after drilling the holes on the radiating plate.

The heat sink according to the present invention has high radiation effect in comparison with the ordinary sink, and therefore, it is possible to reduce the inner temperature of the element.

What is claimed is:

1. A heat sink comprising a heat radiating plate having a plurality of radiating through holes and a plurality of radiating fins formed on said plate, said radiating fins being extended from the surface of said heat radiating plate.

2. A heat sink according to claim 1, wherein said fins are formed by cutting said radiating plate and raising up a plurality of claws to form said fins, and a plurality of through holes formed by making said fins are used as said radiating through holes.

3. A method for manufacturing a heat sink comprising cutting partially a surface of a radiating plate and raising up a plurality of claws so as to extend them from the radiating plate surface and to form radiating through holes and radiating fins.

4. A heat sink comprising a heat radiating plate having a plurality of radiating through holes and a plurality of radiating fins formed on said plate, said radiating fins being extended from the surface of said heat radiating plate, the radiating through holes being shape of rectangular and the radiating fins being positioned in opposition to each other at each side of the radiating through holes, the sum of heights of the fins positioned both sides of said radiating through holes being larger than the distance between the both radiating fins.

5. A heat sink according to claim 1, the thickness of said radiating fins being thinner than that of said radiating plate.

6. A heat sink according to claim 1, the heat radiating fins being arranged along horizontal lines, vertical lines and inclined lines inclined at a predetermined degree to the horizontal and vertical lines so as to allow cooling air to flow along the aligned radiating fins.
